(19) United States
(12) Patent Application Publication
(10) Pub. No.: US 2023/0207289 A1
(43) Pub. Date: Jun. 29, 2023

(54) SUPPORT UNIT AND APPARATUS FOR TREATING SUBSTRATE WITH THE UNIT

(71) Applicant: SEMES CO., LTD., Chungcheongnam-do (KR)

(72) Inventors: Jun Seok PARK, Chungcheongnam-do (KR); Jong Joon JEON, Chungcheongnam-do (KR); Chul Ho JUNG, Gyeonggi-do (KR)

(21) Appl. No.: 18/147,790

(22) Filed: Dec. 29, 2022

(30) Foreign Application Priority Data
Dec. 29, 2021 (KR) 10-2021-0191320
May 2, 2022 (KR) 10-2022-0054432

(51) Int. Cl. H01J 37/32; H01L 21/683

(52) U.S. Cl. CPC H01J 37/32724; H01L 21/6833; H01J 2237/2007; H01J 2237/334

(57) ABSTRACT

An electrostatic chuck of the present invention includes a top block and a bottom block bonded by a bonding layer. The top block has a first plate on which a chucking electrode and a heater are installed, and the bottom block is provided with a cooling member. A second plate made of a material having lower heat transfer rate than the first plate is disposed between the first plate and the bottom block. Accordingly, when the heater is heated at a high temperature, it is possible to prevent the bonding layer from being damaged by thermal impact.

### CROSS-REFERENCE TO RELATED APPLICATIONS

This application claims priority to and the benefit of Korean Patent Application No. 10-2021-0191320 and 10-2022-0054432 filed in the Korean Intellectual Property Office on Dec. 29, 2021, and May 2, 2022, the entire contents of which are incorporated herein by reference.

### TECHNICAL FIELD

The present invention relates to a support unit and an apparatus for treating a substrate with the unit, and more particularly, to an electrostatic chuck for supporting a substrate with an electrostatic force and a substrate treating apparatus for treating the substrate using plasma.

### BACKGROUND ART

Among the processes of manufacturing semiconductors, processes such as etching, deposition, ashing, and drying cleaning require plasma treatment on semiconductor wafers. The plasma treatment process is performed by carrying a wafer into a treatment space provided in a process chamber, and reacting plasma generated from a process gas with a thin film on the wafer, or forming the thin film on the wafer. A support unit for supporting a wafer is provided in the treatment space. An electrostatic chuck for fixing a wafer using an electrostatic force is mainly used as the support unit.

FIG. 1 is a view schematically illustrating a structure of a general electrostatic chuck 900.

The electrostatic chuck has a ceramic puck 920 and a cooling plate 940. Inside the ceramic puck 920, a chucking electrode 922 that adsorbs a wafer disposed on an upper surface thereof with electrostatic force is located, and in the cooling plate 940, a cooling flow path 942 through which cooling water flows is formed. The ceramic puck 920 and the cooling plate 940 are bonded to each other by a bonding layer. In general, the ceramic puck 920 is made of a ceramic material, and the cooling plate 940 is made of a metal material. In addition, the bonding layer 960 is made of a silicon material. Since the heat transfer rate of the bonding layer 960 is much lower than that of the ceramic puck 920 or the cooling plate 940, the bonding layer 960 functions as a thermal barrier layer between the ceramic puck 920 and the cooling plate 940.

For the process of treating the wafer with plasma in a state in which the wafer is heated at a high temperature, a heater 924 is installed in the ceramic puck 920. However, since the bonding layer 960, which is commonly used, does not have high heat resistance, rapid heat transfer from the ceramic puck 920 to the bonding layer 960 occur during heating at high temperature, causing damage to the bonding layer 960 by thermal impact. When the bonding layer 960 is damaged, the temperature of the substrate supported by the electrostatic puck 920 deviates from a predetermined process temperature, resulting in process defects. In addition, when a partial region of the bonding layer 960 is damaged, temperature distribution for each region of the substrate becomes non-uniform.

### SUMMARY OF THE INVENTION

The present invention has been made in an effort to provide an electrostatic chuck that can be stably used even in a high temperature process and an apparatus for treating a substrate with the same.

The present invention has also been made in an effort to provide an electrostatic chuck

having a structure capable of extending the life cycles of a base plate through which cooling water flows and a bonding layer bonding an upper member thereof and an apparatus for treating a substrate with the same.

The object of the present invention is not limited thereto, and other objects not mentioned will be clearly understood by those of ordinary skill in the art from the following description.

An exemplary embodiment of the present invention provides an apparatus for treating a substrate, including: a housing having a treatment space inside; a support unit configured to support the substrate in the treatment space; a gas supply unit configured to supply a treatment gas to the treatment space; and a plasma generating unit configured to generate plasma from the treatment gas, and the support unit includes: an top block on which the substrate is placed; a bottom block disposed under the top block and bonded to the top block by a bonding layer, and provided with a cooling member, and the top block includes: a first plate; and a second plate disposed under the first plate and made of a material having a lower heat transfer rate than the first plate.

According to the exemplary embodiment, each of the first plate and the second plate may be made of a ceramic material, and the first plate and the second plate may be integrally provided by sintering.

According to the exemplary embodiment, the apparatus for treating a substrate further includes: a porous layer disposed under the first plate; and a gas supply line configured to supply gas to the porous layer.

According to the exemplary embodiment, the porous layer may be inserted into the second plate.

According to the exemplary embodiment, the porous layer may be disposed under the second plate.

According to the exemplary embodiment, the apparatus for treating a substrate further includes a third plate disposed under the second plate and made of a material having a lower heat transfer rate than the second plate.

According to the exemplary embodiment, the third plate may be made of a material with a higher heat expansion rate than the second plate.

According to the exemplary embodiment, the second plate may be made of a material with a higher heat expansion rate than the first plate.

According to the exemplary embodiment, the first plate and the second plate may be made of the same material, and the type and content of impurities contained in the first plate may be different from the type and content of impurities contained in the second plate.

According to the exemplary embodiment, the first plate may include a heating member configured to heat the substrate.

Another exemplary embodiment of the present invention provides an electrostatic chuck for chucking the substrate with an electrostatic force, including: an top block on which the substrate is placed; a bottom block disposed under the top block and bonded to the top block by a bonding layer and provided with a cooling member, and the top block includes: a first plate in which a chucking electrode and a heating member are installed; and a second plate disposed under the first plate and made of a material having a lower heat transfer rate than the first plate.

According to the exemplary embodiment, each of the first plate and the second plate may be made of a ceramic material, and the first plate and the second plate may be integrally provided by sintering.

According to the exemplary embodiment, the electrostatic chuck further includes: a porous layer disposed under the first plate; and a gas line configured to supply gas to the porous layer.

According to the exemplary embodiment, the electrostatic chuck further includes: a third plate disposed under the second plate and provided with a material having a lower heat transfer rate than the second plate.

According to the exemplary embodiment, the third plate may made of a material with a higher heat expansion rate than the second plate.

According to the exemplary embodiment, the second plate may be made of a material having a higher heat expansion rate than the first plate.

Still another exemplary embodiment of the present invention provides an apparatus for treating a substrate, including: a housing having a treatment space inside; an electrostatic chuck configured to support the substrate by an electrostatic force in the treatment space; a gas supply unit configured to supply a treatment gas to the treatment space; and a plasma generating unit configured to generate plasma from the treatment gas, and the electrostatic chuck includes: an top block on which the substrate is placed; a bottom block disposed under the top block and bonded to the top block by a bonding layer, and having a flow path through which a cooling fluid flows, the bonding layer is provided as a thermal barrier layer, and the top block includes: a first plate provided with a heater and a chucking electrode; a second plate disposed under the first plate and made of a material having lower heat transfer rate than the first plate; and a third plate disposed under the second plate and provided with a material having a lower heat transfer rate than the second plate.

According to the exemplary embodiment, the first plate and the second plate may be made of the same material, and the type and content of impurities contained in the first plate may be different from the type and content of impurities contained in the second plate.

According to the exemplary embodiment, the material of the bonding layer includes silicon, and the materials of the first plate and the second plate include aluminum nitride, and the material of the third plate includes yttria or cordierite.

According to the exemplary embodiment, the apparatus for treating a substrate further includes: a porous layer disposed inside the second plate or between the second plate and the third plate; and a gas line configured to supply gas to the porous layer.

According to the exemplary embodiment of the present invention, the bonding layer provided in the electrostatic chuck can be prevented from being damaged by thermal impact in the plasma treatment process.

In addition, according to the exemplary embodiment of the present invention, it is possible to improve the life cycle of the electrostatic chuck in the plasma treatment process.

In addition, according to the exemplary embodiment of the present invention, the temperature of the substrate may be maintained at a set temperature in a whole region of the substrate in the plasma treatment process.

### BRIEF DESCRIPTION OF THE DRAWINGS

FIG. 1 is a cross-sectional view schematically illustrating a structure of a generally used electrostatic chuck.

FIG. 2 is a top plan view schematically illustrating an apparatus for treating a substrate according to one embodiment of the present invention.

FIG. 3 is a cross-sectional view schematically illustrating an example of a process chamber of FIG. 2.

FIG. 4 is a cross-sectional view schematically illustrating the structure of a shower head unit of FIG. 3.

FIG. 5 is a cross-sectional view schematically illustrating the structure of a support unit of FIG. 3.

FIG. 6 is a top plan view schematically illustrating an upper surface of a ceramic puck of FIG. 5.

FIGS. 7 to 12 are views respectively illustrating various modified examples of the electrostatic chuck of FIG. 4.

FIG. 13 is a view schematically illustrating a modified example of an apparatus for treating a substrate of FIG. 2.

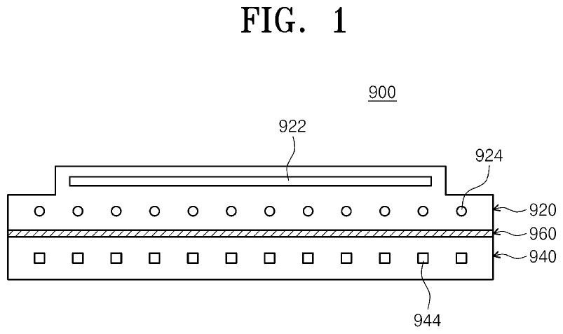

### DETAILED DESCRIPTION

Hereinafter, exemplary embodiments of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

In the exemplary embodiment of the present invention, a substrate will be described as an example of a circular substrate W such as a semiconductor wafer. However, in the present invention, the substrate may be a substrate with a rectangular shape such as a mask or a display panel.

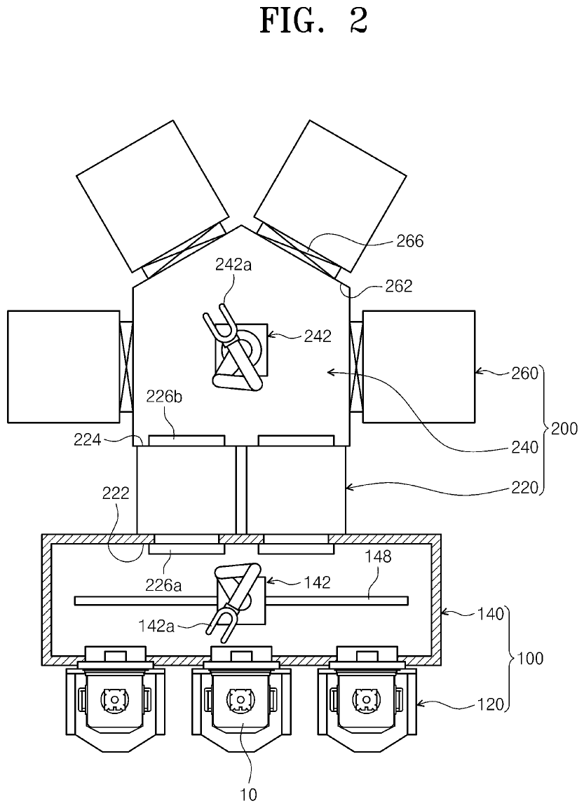

FIG. 2 is a top plan view schematically illustrating an apparatus for treating a substrate according to one embodiment of the present invention. Referring to FIG. 2, the apparatus 1 for treating a substrate includes a equipment front end module 100 and a treating module 200. The equipment front end module 100 and the treating module 200 are disposed in one direction.

The equipment front end module 100 transfers the substrate W from the container 10 in which the substrate W is accommodated, to the treating module 200, and accommodates the substrate W that has been treated in the treating module 200, into the container 10. A longitudinal direction of the equipment front end module 100 is provided in a second direction. The equipment front end module 100 has a load port 120 and an index frame 140. The load port 120 is disposed in an opposite side of the treating module 200 based on the index frame 140. The container 10 in which the substrates W are accommodated is placed in the load port 120. A plurality of load ports 120 may be provided.

As the container 10, a sealing container 10 such as a front open unified pod (FOUP) may be used. The container 10 may be placed in the load port 120 by an operator or a transport means (not illustrated) such as an overhead transfer, an overhead conveyor, or an automatic guided vehicle.

The index frame 140 may have a sealed space from the outside. A space in the index frame 140 may be provided with atmospheric pressure. Optionally, the space in the index frame 140 may be provided at a pressure higher than the atmospheric pressure. A fan filter unit (not illustrated) is provided in an upper end of the index frame 140. The fan filter unit forms a downward airflow in the index frame 140. A door opener (not illustrated) for opening or closing a door of the container 10 may be provided in the index frame 140.

An index robot 142 is provided in the index frame 140. Within the index frame 140, a guide rail 148 in which a longitudinal direction is provided in the second direction may be provided, and the index robot 142 may be provided to be movable on the guide rail 148. The index robot 142 includes a hand 142a on which the substrate W is placed, and the hand 142a may be provided to move forward and backward, rotate around a vertical direction as an axis, and move up and down. A plurality of hands 142a may be spaced apart from each other in the vertical direction, and the hands 142a may move forward and backward independently from each other.

The treating module 200 includes a load lock chamber 220, a transfer chamber 240, and a process chamber 260. The load lock chamber 220 is disposed adjacent to the index frame 140. The load lock chamber 220 may be disposed between the transfer chamber 240 and the equipment front end module 100. The substrate W transferred from the container 10 to the process chamber 260 may be temporarily stored in the load lock chamber 220 after being carried out of the container 10. In addition, the substrate W whose process has been completed in the process chamber 260 may be temporarily stored in the load lock chamber 220 while being transferred to the container 10.

The load lock chamber 220 is provided such that an interior thereof may be converted between a first pressure and a second pressure. The first pressure is the same as or similar to the pressure in the index frame 140, and the second pressure is the same as or similar to the pressure in the transfer chamber 240. For example, the first pressure may be atmospheric pressure, and the second pressure may be vacuum pressure. Among the walls of the load lock chamber 220, a front wall 222 facing the index frame 140 and a rear wall 224 facing the transfer chamber 240 are each provided with an entrance (not illustrated) through which the substrate W is carried in. The entrance is opened or closed by a doors 226a and 226b. A purge gas supply line 640 (not illustrated) and a decompression line (not illustrated) are connected to the load lock chamber 220. Before the door 226a provided on the front wall 222 is opened, in a state in which the doors 226a and 226b provided on the front wall 222 and the rear wall 224 is closed, a purge gas is supplied to the load lock chamber 220 through the purge gas supply line 640, and the pressure in the load lock chamber 220 is converted from the second pressure to the first pressure. In addition, before the door 226b provided on the rear wall 224 is opened, a gas in the load lock chamber 220 is discharged through the decompression line, and accordingly, the pressure in the load lock chamber 220 is converted from the first pressure to the second pressure.

A plurality of load lock chambers 220 may be provided. The substrate W may be transferred between the index frame 140 and the transfer chamber 240 through each of the load lock chambers 220. Optionally, the substrate W may be transferred from the index frame 140 to the transfer chamber 240 through one of the load lock chambers 220, and may be transferred from the transfer chamber 240 to the index frame 140 through the other of the load lock chambers 220.

The transfer chamber 240 is disposed adjacent to the load lock chamber 220. When viewed from the top, the transfer chamber 240 may be provided in a polygonal shape. A transfer robot 242 is disposed in the transfer chamber 240. The transfer robot 242 transfers the substrate W between the load lock chamber 220 and the process chamber 260. The interior of the transfer chamber 240 may be provided as the vacuum pressure.

The transfer robot 242 includes a hand 242a on which the substrate W is placed, and the hand 242a may be provided to move forward and backward, rotate around the vertical direction an axis, and move up and down. A plurality of hands 242a may be spaced apart from each other in the vertical direction, and the hands 242a may move forward and backward independently from each other. One of the hands 242a may support the substrate W transferred from the load lock chamber 220 to the process chamber 260, and the other of the hands 242a may support the substrate W transferred from the process chamber 260 to the load lock chamber 220.

The process chamber 260 is disposed on a side part of the transfer chamber 240. For example, the process chamber 260 may be disposed on each side of the transfer chamber 240. The process chambers 260 may be provided to perform the same process on the substrate W. Optionally, some of the process chambers 260 may be provided to sequentially perform a series of processes on the substrate W. According to the exemplary embodiment, the process chamber 260 may perform a process of treating the substrate W using plasma. For example, the process chamber 260 may perform a process of etching a thin film on the substrate W.

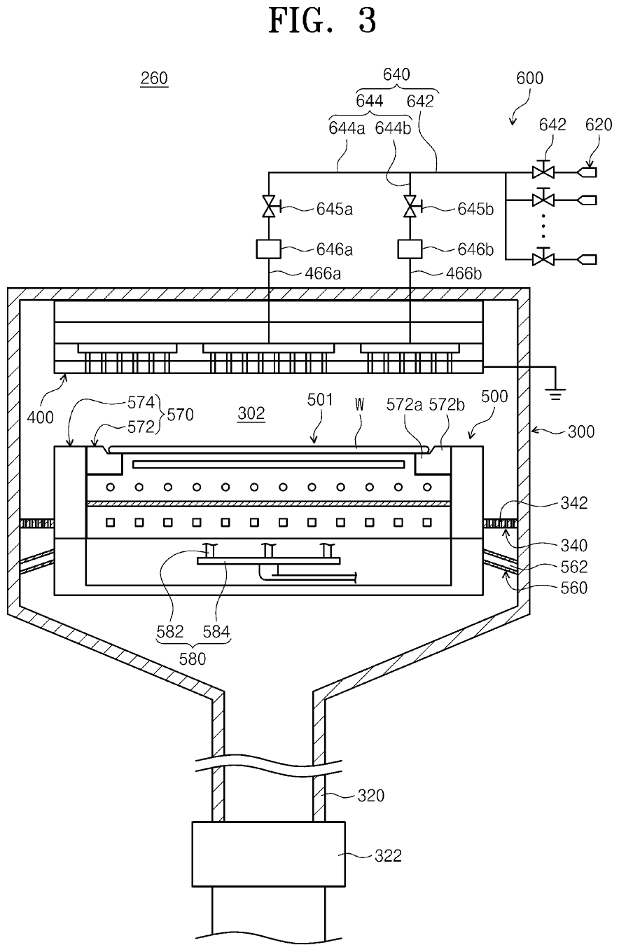

FIG. 3 is a cross-sectional view schematically illustrating an example of the process chamber of FIG. 2.

Referring to FIG. 3, the process chamber 260 includes a housing 300, a shower head unit 400, and a support unit 500.

The housing 300 is provided in a substantially rectangular parallelepiped shape. The housing 300 has a treating space 302 in which the substrate W is carried in and a predetermined process is performed on the substrate W. An entrance (not illustrated) through which the substrate W is carried in and out is formed on a wall 262 facing the transfer chamber 240 among the walls of the housing 300. The entrance may be opened or closed by the door 266.

The support unit 500 supports the substrate W in the treating space 302. The support unit 500 is disposed in a lower part of the treating space 302. The support unit 500 includes an electrostatic chuck 501 for supporting the substrate W using an electrostatic force. Optionally, the support unit 500 may support the substrate W by vacuum pressure or a mechanical clamp. A detailed structure of the support unit 500 will be described below.

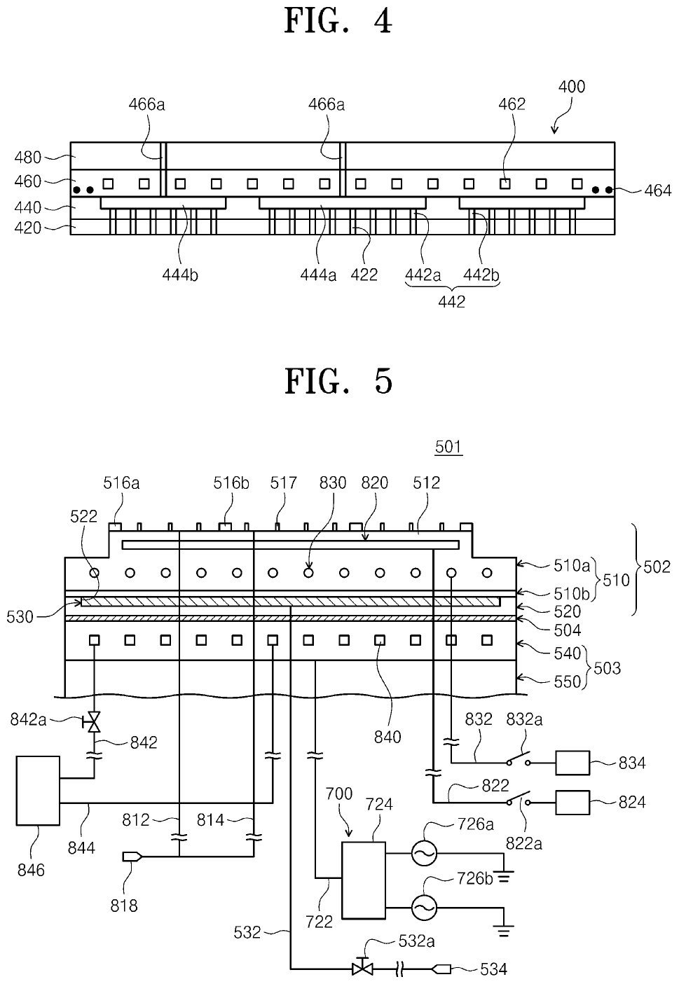

The shower head unit 400 is disposed in an upper part of the treating space 302. The shower head unit 400 is disposed to face the support unit 500. FIG. 4 is a cross-sectional view schematically illustrating a structure of the shower head unit. Referring to FIG. 4, the shower head assembly 400 has a shower head electrode 420, a backing plate 440, a temperature control plate 460, and an upper plate 480.

The shower head electrode 420 has a circular plate shape. The shower head electrode 420 may have a diameter greater than that of the substrate W supported by the support unit 500. The shower head electrode 420 may be made of a material including silicon. For example, the shower head electrode 420 may be made of single crystalline silicon. The shower head electrode 420 may be grounded. High frequency power may be selectively applied to the shower head electrode 420. A plurality of injection holes 422 are formed in the shower head electrode 420. The injection hole 422 extends from an upper surface to a lower surface of the shower head electrode 420. A formation density of the injection hole 422 may be the same over a whole region of the shower head electrode 420. Optionally, the injection hole 422 may have different formation densities of the injection hole 422 depending on a region of the shower head electrode 420.

The shower head electrode 420 may be supported by the backing plate 440. The backing plate 440 is disposed on the shower head electrode 420. The backing plate 440 may be provided in a substantially disk shape. The backing plate 440 may be provided with a diameter similar to that of the shower head electrode 420. The shower head electrode 420 may be attached to the backing plate 440 by an adhesive. Optionally, the shower head electrode 420 may be coupled to the backing plate 440 by a mechanical coupling means such as a bolt. The backing plate 440 has a plurality of connection holes 442 formed therein. The connection hole 442 extends from an upper surface to a lower surface of the backing plate 440. When viewed from the top, the connection holes 442 may be aligned with the injection holes 422 formed in the shower head.

The temperature control plate 460 is formed on the backing plate 440. The temperature control plate 460 has a circular plate shape. The temperature control plate 460 may be provided with a diameter similar to that of the backing plate 440. The backing plate 440 may be coupled to the temperature control plate 460 by the mechanical coupling means such as a bolt. Optionally, the backing plate 440 may be attached to the temperature control plate 460 by the adhesive.

The temperature control plate 460 has a cooling flow path 462 through which a cooling fluid flows. The cooling flow path 462 may be formed over a whole region of the temperature control plate 460. Cooling water may be used as the cooling fluid. In addition, a heater 464 may be provided in the temperature control plate 460. A heating wire may be used as the heater 464. An alternating current may be applied to the heating wire. The heater 464 may be disposed in an edge part of the temperature control plate 460. For example, the heater 464 may be disposed more externally than the cooling flow path 462. Optionally, the heater 464 may be disposed over the whole region of the temperature control plate 460.

A center groove 444a and an edge groove 444b are formed in an upper surface of the backing plate 440. The center groove 444a may be provided in a circular shape. The edge groove 444b may be provided in a ring shape. The center groove 444a and the edge groove 444b are spaced apart from each other. By the combination of the temperature control plate 460 and the backing plate 440, the center groove 444a and the edge groove 444b each function as a buffer space where the gas stays. Connection holes 442a formed in a center region of the backing plate 440 are provided to communicate with the center groove 444a, and connection holes 442b formed in an edge region of the backing plate 440 are provided to communicate with the edge groove 444b. In addition, a center gas inlet 466a and an edge gas inlet 466b are formed in the temperature control plate 460 and the upper plate 480. The center gas inlet 466a is provided to communicate with the center groove 444a, and the edge gas inlet 466b is provided to communicate with the edge groove 444b. Due to the above-described structure, a gas introduced through the center gas inlet 466a flows downwardly through the center groove 444a formed in the backing plate 440, the connection holes 442a formed in the backing plate 440, and the injection hole 422 of the shower head electrode 420. In addition, a gas introduced through the edge gas inlet 466b flows downwardly through the edge groove 444b formed in the backing plate 440, the connection holes 442b formed in the backing plate 440, and the injection hole 422 of the shower head electrode 420.

The temperature control plate 460 is coupled to the upper plate 480. The upper plate 480 is disposed on the temperature control plate 460. The temperature control plate 460 may be coupled to the upper plate 480 by the mechanical coupling means such as a bolt. The upper plate 480 has a substantially circular plate shape. The upper plate 480 may be coupled to an upper wall of the housing 300.

The gas supply unit 600 supplies a treatment gas into the housing 300. The treatment gas includes an etching gas. The etching gas is selected according to an etching target layer on the substrate W. When the etching target film is a silicon film, the treatment gas may include a fluorine-based gas. For example, the treatment gas may include SF6, NF3, CF4, or a combination thereof. When the etching target film is a silicon oxide film, the treatment gas may include a fluorocarbon-based gas. For example, the treatment gas may include CF4, C2F6, C3F8, C4F8, CHF3, or a combination thereof. When the etching target layer is a silicon nitride layer, the treatment gas may include a fluorocarbon-based gas. For example, the treatment gas may include CFx gas. Furthermore, the treatment gas may further include an additive gas so as to improve an etching selection ratio or stabilize plasma. For example, the additive gas may be oxygen, nitrogen, helium, hydrogen, argon, or a combination thereof.

The gas supply unit 600 has a gas supply source 620 and a gas supply line 640. A plurality of gas supply sources 620 are provided. Each gas supply source 620 stores different gases. Each of the gas supply lines 640 are connected to the gas supply source 620. The gas supply line 640 has a main line 642 and a branch line 644. The main line 642 is connected to the gas supply source 620. The main line 642 branches into two branch lines 644. A first line 644a, which is one of the branch lines 644, is connected to the center gas inlet 466a. A second line 644b, which is the other of the branch lines 644, is connected to the edge gas inlet 466b. An opening/closing valve 642 is installed in the main line 642. Opening and closing valves 645a and 645b are installed on the first line 644a and the second line 644b, respectively. Furthermore, flow rate regulators 646a and 646b are installed in each of the first line 644a and the second line 644b. Optionally, the flow rate regulators may be installed in one of the first line 644a and the second line 644b and the main line 642.

Due to the above-described structures of the shower head unit 400 and the gas supply unit 600, when supplying gas to the treating space 302, the amount of gas supplied to the center space 302 and the amount of gas supplied to the edge space 302 can be regulated, respectively.

However, unlike the foregoing description, only a single groove is formed in a bottom surface of the temperature control plate 460, and the gas supply line 640 may have only a main line 642 without a branch line 644. Optionally, the number of grooves formed in the temperature control plate 460 and the number of branch lines 644 may be three or more.

FIG. 5 is a cross-sectional view schematically illustrating the structure of a support unit. Referring to FIG. 5, the support unit 500 includes an electrostatic chuck 501. The electrostatic chuck 501 has a top block 502 and a bottom block 503. The top block 502 is disposed above the bottom block 503. The top block 502 and the bottom block 503 are bonded to each other by a bonding layer 504. The bonding layer 504 may function as a thermal barrier layer. The bonding layer 504 may be made of a material containing silicon. The bonding layer 504 may be provided as a single layer or as a composite layer. For example, the bonding layer 504 may be provided in a plural form sequentially disposed from top to bottom. A plurality of layers may be made of different materials.

The top block 502 has a ceramic puck 510, a buffer plate 520, and a porous layer 530. The ceramic puck 510 is disposed on the porous layer 530. The porous layer 530 is disposed higher than the buffer plate 520.

The ceramic puck 510 has an upper plate 510a and a lower plate 510b. The upper plate 510a has a central portion 512 and an edge portion 514 extending outward therefrom. When viewed from the top, the central portion 512 may be provided in a circular shape, and the edge portion 514 may be provided in an annular shape. The height of an upper surface of the central portion 512 of the upper plate 510a is provided higher than the height of an upper surface of the edge portion 514 of the upper plate 510a. The diameter of the central portion 512 is provided smaller than the diameter of the substrate W. Accordingly, the substrate W is supported on the central portion 512 of the upper plate 510a.

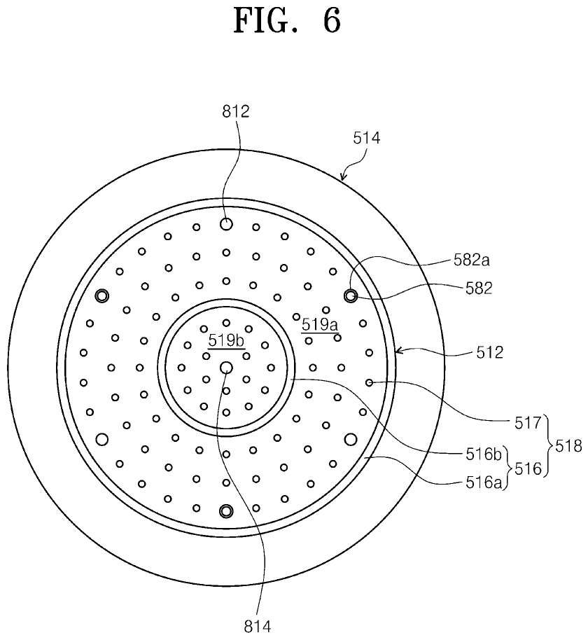

FIG. 6 is a top plan view schematically illustrating an upper surface of the ceramic puck. Referring to FIG. 6, a projection 518 in contact with a bottom surface of the substrate W is provided on an upper surface of the upper plate 510a. The projection 518 may have a ring-shaped projection 516. The ring-shaped projection 516 may include an outer projection 516a formed in an end of the upper plate 510a. Furthermore, the ring-shaped projection 516 may further include an inner projection 516b disposed more inwardly than the outer projection 516a. The outer projection 516a and the inner projection 516b may be provided at the same height. In addition, the projection 518 may further include a point-shaped projection 517. A plurality of point-shaped projections 517 are provided in an outer space 519a surrounded by the inner projection 516b and the outer projection 516a. Furthermore, the plurality of point-shaped projections 517 are provided in the inner space 519b surrounded by the inner projections 516b. The substrate W may be directly supported by the outer projection 516a, the inner projection 516b, and the point-shaped projections 517.

Heat transfer gas is supplied to the outer space 519a and the inner space 510b, respectively. The heat transfer gas may be helium gas. A first heat transfer gas line 812 is connected to the inner space 519b, and a second heat transfer gas line 814 is connected to the outer space. The first heat transfer gas line 812 and the second heat transfer gas line 814 receive heat transfer gas from the heat transfer gas source 818. The state or supply amount of the heat transfer gas supplied through the first heat transfer gas line 812 may be different from the state or supply amount of the heat transfer gas supplied through the second heat transfer gas line 814. The state of the heat transfer gas may include the temperature of the heat transfer gas. The supply amount of the heat transfer gas may include a supply amount per unit time. An opening/closing valve, a flow rate regulator, or a heater may be installed in each of the first heat transfer gas line 812 and the second heat transfer gas line 814.

A chucking electrode 820 is disposed in the central portion 512 of the upper plate 510a. The chucking electrode 820 is electrically connected to a DC power source 824 via a conductive wire 822. A switch 822a may be installed in the conductive wire 822. When a voltage is applied to the chucking electrode 820 from the DC power source 824, the substrate W is chucked to the upper plate 510a by an electrostatic force.

The upper plate 510a may be provided with a heating member 830. The heating member 830 may be disposed in the upper plate 510a under the chucking electrode 820. The heating member 830 includes a resistive heater. For example, the resistive heater may be a heating wire. The resistive heater is electrically connected to an AC power source 834 through a conductive wire 832. A switch 832a may be installed in the conductive wire 832. For example, the resistive heater may be heated to a temperature of 150° C. or higher during the process.

The lower plate 510b is disposed under the upper plate 510a. The lower plate 510b has a circular plate shape. The lower plate 510b may have a diameter substantially the same as that of the bottom surface of the upper plate 510a. The lower plate 510b is made of a material having a lower heat transfer rate than the upper plate 510a. Since the lower plate 510b is made of a material having a lower heat transfer rate than the upper plate 510a, high-temperature heat is quickly transmitted from the upper plate 510a to the bonding layer 504 to prevent the bonding layer 504 from being damaged by thermal impact. The upper plate 510a and the lower plate 510b may be integrally provided by sintering.

The lower plate 510b is made of a material having a higher heat expansion rate than the upper plate 510a. Since the heating member 830 is embedded in the upper plate 510a, the temperature of the upper plate 510a is higher than the temperature of the lower plate 510b. Therefore, if the lower plate 510b is made of a material having the same heat expansion rate as the upper plate 510a or a material having a heat expansion rate smaller than the upper plate 510a, the degree of thermal expansion between the upper plate 510a and the lower plate 510b may be different to cause damage to the upper plate 510a or the lower plate 510b. However, if the lower plate 510b is made of a material having a higher heat expansion rate than the upper plate 510a, the degree of thermal expansion between the upper plate 510a and the lower plate 510b can be reduced, thereby minimizing damage to the upper plate 510a and the lower plate 510b due to the thermal expansion.

The buffer plate 520 is disposed under the lower plate 510b. The buffer plate 520 has a circular plate shape. The buffer plate 520 may be provided with the same diameter as the diameter of the lower plate 510b. The buffer plate 520 may be coupled to the ceramic puck 510 by the mechanical coupling means (not illustrated) such as a bolt. The buffer plate 520 is made of a material having a lower heat transfer rate than the lower plate 510b. Furthermore, the buffer plate 520 may be made of a material having a higher heat expansion rate than the lower plate 510b. The heat transfer rate is reduced through multiple steps by the lower plate 510b and the buffer plate 520 until heat generated from the heater 830 of the upper plate 510a reaches the bonding layer 504, thereby further mitigating a heat impact applied to the bonding layer 504.

Each of the upper plate 510a and the lower plate 510b is made of a ceramic material. The upper plate 510a and the lower plate 510b may be made of the same material. In this case, the types and contents of impurities contained in the materials of the upper plate 510a and the lower plate 510b may be provided differently so as to regulate the heat transfer rate and the heat expansion rate of the upper plate 510a and the lower plate 510b. According to the exemplary embodiment, the upper plate 510a and the lower plate 510b may be made of aluminum nitride. According to the type and content of impurities, the heat transfer rate of commonly used aluminum nitride is about 70 to 180 (W/mk), and the heat expansion rate of aluminum nitride is about 3.9 to 4.6 (10⁻⁶/° C.). The buffer plate 520 may be made of a ceramic material. The buffer plate 520 may be made of a material different from that of the upper plate 510a and the lower plate 510b. For example, the material of the buffer plate 520 may be provided as yttria. According to the type and content of impurities, the commonly used yttria have a heat transfer rate of about 16 to 17.2 (W/mk) and a heat expansion rate of about 10 to 11.5 (10⁻⁶/° C.). Furthermore, the commonly used cordierite has a heat transfer rate of about 4 (W/mk), and a heat expansion rate of about 1.5 to 2.1 (10⁻⁶/° C.).

Optionally, the materials of the upper plate 510a and the lower plate 510b may be provided as alumina, and the material of the buffer plate 520 may be provided as zirconia. Alumina has a heat transfer rate of about 30 (W/mk) and a heat expansion rate of about 7.2 (10⁻⁶/° C.). In addition, zirconia has a heat transfer rate of about 3 (W/mk) and a heat expansion rate of about 10.5 (10⁻⁶/° C.). These heat transfer rates and heat expansion rates may be regulated according to the type and content of impurities.

The porous layer 530 may be provided between the lower plate 510b and the buffer plate 520. According to the exemplary embodiment, an insertion groove 522 may be formed on the upper surface of the buffer plate 520, and the porous layer 530 may be disposed in a space surrounded by the buffer plate 520 and the lower plate 510b. The thickness of the porous layer 530 may be provided similar to the thickness of the insertion groove 522. An upper surface of the porous layer 530 may be in contact with the lower plate 510b, and a lower surface of the porous layer 530 may be in contact with the buffer plate 520. A gas line 532 is connected to the porous layer 530. The gas line 532 supplies gas stored in a gas supply source 534 to the porous layer 530. An opening/closing valve 532a may be installed in the gas line 532. The gas supplied to the porous layer 530 may be helium gas. The gas selectively supplied to the porous layer 530 may be different types of inert gas such as nitrogen, etc.

When the porous layer 530 through which an inert gas is supplied is provided on a heat transmission path between the upper plate 510a and the bonding layer 504, heat transmission may be suppressed as compared to a case where a heat transmission path is performed only by the conduction through plates such as the lower plate 510b and the buffer plate 520. Furthermore, when the inert gas is supplied into an empty space having a certain volume, the structural strength is reduced due to the empty space. However, according to the exemplary embodiment of the present invention, structural stability may be maintained by filling a region to which the inert gas is supplied, with the porous layer 530.

The bottom block 503 includes a cooling plate 540 and a support 550. The cooling plate 540 adheres to the top block 502 by the bonding layer 504. The cooling plate 540 has a circular plate shape. A cooling flow path 840 through which a cooling fluid flows is formed inside the cooling plate 540. Cooling water may be used as the cooling fluid. The cooling flow path 840 receives the cooling water from a cooling water supply source 846 through a cooling water supply line 842. Further, the cooling water flowing through the cooling flow path 840 is recovered to the cooling water supply source 846 through the cooling water recovery line 844. An opening/closing valve 842a may be installed in the cooling water supply line 842. The cooling plate 540 is made of a metal material. For example, the cooling plate 540 may be made of aluminum. A high frequency power source 726a is connected to the cooling plate 540 through a high frequency line 722. The high frequency power supply 726a applies high frequency power to the cooling plate 540. The high frequency power generates plasma from the treatment gas supplied between the shower head unit 400 and the support unit 500. In addition, a bias power source 726b is connected to the cooling plate 540 through a high frequency line 722. The bias power supply 726b introduces ions contained in the plasma into the substrate W supported by the electrostatic chuck 502. A matcher 724 is installed in the high frequency line 722.

A plasma generating unit generates plasma in the treating space 302 in the housing 300.

According to the exemplary embodiment of the present invention, the shower head electrode 420 and the cooling plate 540 function as electrodes for plasma generation, respectively.

The support 550 is disposed under the cooling plate 540. The support 550 has a cylindrical shape having an inner space.

The support unit 500 may be fixed to the chamber by a support rod 560. One end of the support rod 560 is fixed to the housing 300, and the other end of the support rod 560 is fixed to the support assembly 560. A plurality of support rods 560 are provided. For example, three support rods 560 are provided, and when viewed from the top, the support rods 560 may be disposed at equal intervals. Some or all of the support rods 560 have a through hole 562 therein. Plenty of gas lines 532, 812 and 814, the cooling water lines 842 and 844, and conductive wires 722, 822 and 832 supplied to the electrostatic chuck 501 may be inserted into an inner space of the support 550 from the outside of the housing 300 through the through hole (562).

An exhaust pipe 320 is connected to a bottom wall of the housing 300. According to the example embodiment, the support unit 500 may be spaced upwardly from the bottom wall of the housing 300, and the exhaust pipe 320 may be connected to the center of the bottom wall of the housing 300. A pump 322 is connected to the exhaust pipe 320. The pump 322 maintains the pressure in the treating space 302 to a predetermined pressure during the process. In addition, the pump 322 exhausts reaction byproducts generated during the process through the exhaust pipe. The pump 322 may be a turbo pump. A ring-shaped exhaust baffle 340 may be provided between an inner wall of the housing 300 and an outer wall of the support unit 500. A plurality of exhaust holes 342 penetrated in a vertical direction are formed in the exhaust baffle 340. The exhaust baffle 340 may be disposed above the support rod 560.

The support unit 500 further includes a ring kit 570. The ring kit 570 includes a plurality of ring members surrounding the perimeter of the electrostatic chuck 501. According to the exemplary embodiment, the ring kit 570 includes an edge ring 572 and an insulating ring 574.

The edge ring 572 may be made of a conductive material. For example, the edge ring 572 is made of a material containing silicon. The edge ring 572 adjusts plasma sheath in an edge region of the substrate W. The edge ring 572 is provided to surround the central portion 512 of the upper plate 510a. The edge ring 572 has an inner portion 572a and an outer portion 572b. The inner portion 572a of the edge ring 572 is placed on the edge portion 514 of the upper plate 510a. An upper surface of the inner part 572a of the edge ring 572 is disposed at the same height as an upper surface of the central portion 512 of the upper plate 510a. Optionally, an upper surface of the inner portion 572a of the edge ring 572 may be disposed at a height lower than an upper surface of the center portion 512 of the upper plate 510a. The outer portion 572b of the edge ring 572 extends outwardly from the inner portion 572a of the edge ring 572. An upper surface of the outer portion 572b of the edge ring 572 may be disposed at a height higher than the upper surface of the inner portion 572a of the edge ring 572. For example, the upper surface of the outer portion 572b of the edge ring 572 may be disposed higher than an upper surface of the substrate W placed on the electrostatic chuck 501. That is, an upper surface of the edge ring 572 is stepped so that the height of the edge ring 572 may decrease from the outside to the inside. Due to the above-described structure, a central region of the substrate W is supported by the central portion 512 of the upper plate 510a, and the edge region of the substrate W is supported by the inner portion 572a of the edge ring 572.

The insulating ring 574 is disposed to surround the edge ring 572 and the electrostatic chuck 501. The insulating ring 574 is made of an insulating material. For example, the insulating ring 574 may be made of a quartz material. The insulating ring 574 protects an outer surface of the electrostatic chuck 501 and the outer surface of the edge ring 572 from plasma during the process using plasma.

In addition, the support unit 500 further includes a pin unit 580. The pin unit 580 takes over the substrate W between the electrostatic chuck 501 and an external transfer robot. The pin unit 580 has a plurality of lift pins 582, a pin support 584, and an elevation driver (not illustrated). A plurality of pin holes 582a penetrated in the vertical direction are formed in the electrostatic chuck 501. Each of lift pins 582 is provided to be movable vertically along the pin hole 582a disposed to correspond to the lift pins 582. The plurality of lift pins 582 are installed on the pin support 584. The pin support 584 may be disposed in a lower part of the electrostatic chuck 501. For example, the pin support 584 may be disposed in the inner space of the support 550. The pin support 584 is moved in the vertical direction by the elevation driver. The pin support 584 may be moved between an up position and a down position. The up position is a position in which the lift pin 582 protrudes above the electrostatic chuck 501. The down position is a position in which an upper end of the lift pin 582 is inserted into the pin hole 582a.

The transfer of the substrate W from the transfer robot to the electrostatic chuck 501 is as follows. The pin support 584 is moved to the up position. The transfer robot transfers the substrate W to a position corresponding to the pin support 584. The substrate W supported by the transfer robot by a descending operation of the transfer robot is transferred to the lift pin 582. The pin support 584 is moved from the up position to the down position. As the lift pin 582 descends, the substrate W supported by the lift pin 582 is transferred onto the electrostatic chuck 501. The transfer of the substrate W from the electrostatic chuck 501 to the transfer robot is performed by an operation in the opposite way thereof.

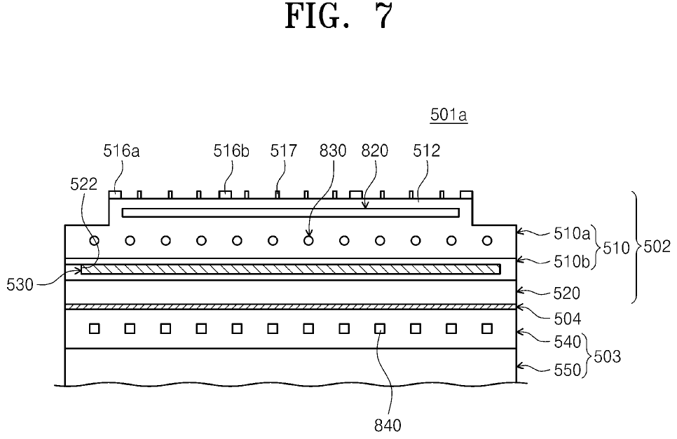

FIG. 5 has illustrated that in the electrostatic chuck 50, the porous layer 530 is disposed between the ceramic puck 510 and the buffer plate 520. However, in contrast, the porous layer 530 may be disposed in the ceramic puck 510. For example, in the electrostatic chuck 501a, the porous layer 530 may be inserted into the lower plate 510b of the ceramic puck 510 as illustrated in FIG. 7.

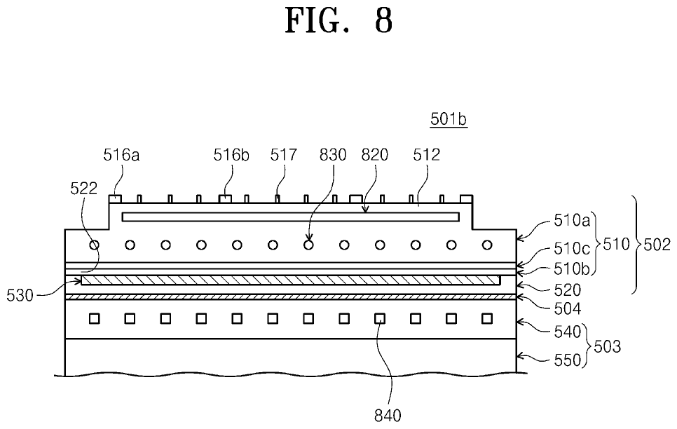

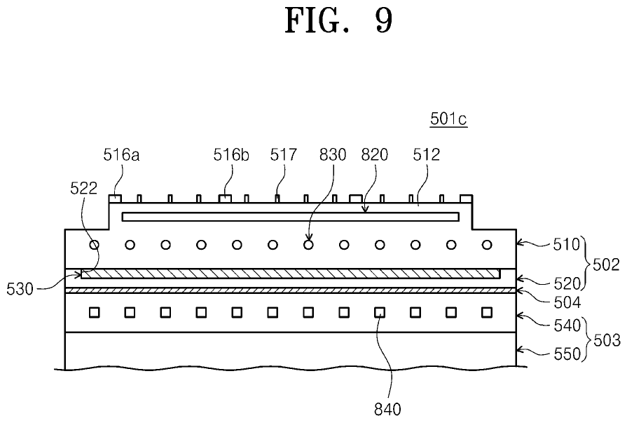

In addition, in FIG. 5, it has been described that in the electrostatic chuck 501, the ceramic puck 510 has two plates having different heat transfer rate. However, in contrast, the ceramic puck 510 may include three or more plates having different heat transfer rate. For example, as illustrated in FIG. 8, in the electrostatic chuck 501b, the ceramic puck 510 may include an upper plate 510a, an intermediate plate 510c, and a lower plate 510b. The upper plate 510a, the intermediate plate 510c, and the lower plate 510b may be sequentially disposed from a top portion to a bottom portion, and the materials of these plates 510a, 510b and 510c may be provided such that the heat transfer rate thereof gradually decreases from a top portion to a bottom portion. Furthermore, the materials of these plates 510a, 510b and 510c may be provided such that the heat expansion rate thereof gradually increases from a top portion to a bottom portion. Optionally, as illustrated in FIG. 9, the electrostatic chuck 501c may have only one plate.

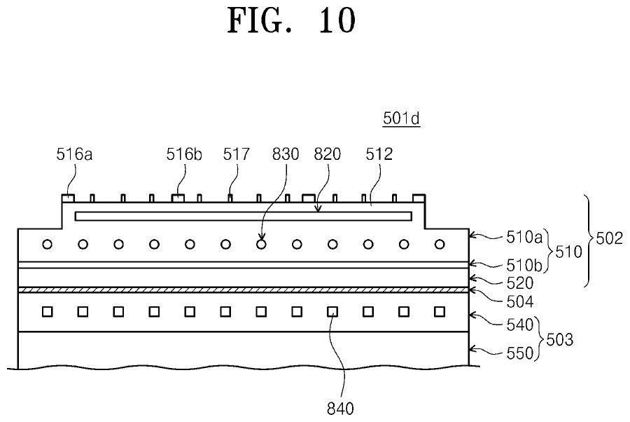

In addition, in FIG. 5, it has been described that the electrostatic chuck 501 includes the porous layer 530 and the gas lines. However, as illustrated in FIG. 10, the porous layer 530 and the gas lines may not be provided in the electrostatic chuck 501d.

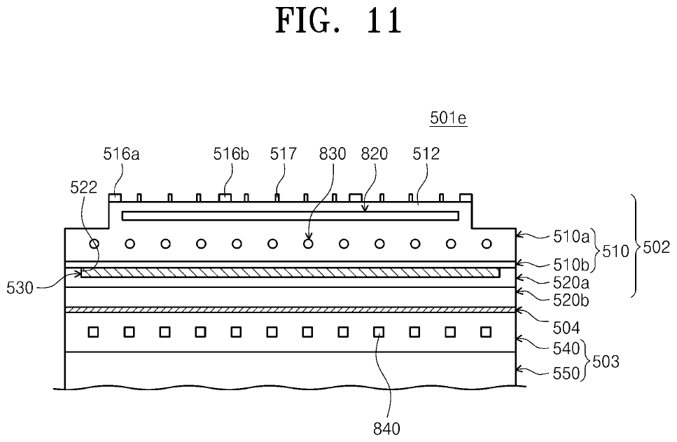

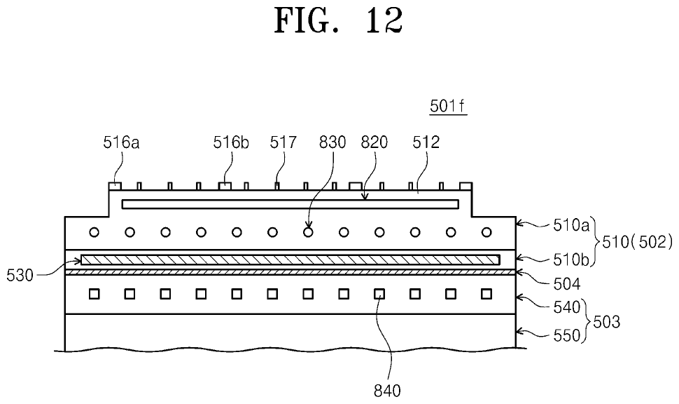

In addition, in FIG. 5, it has been described that the electrostatic chuck 501 includes one buffer plate 520. However, as illustrated in FIG. 11, the electrostatic chuck 501e may include a plurality of buffer plates 520a and 520b. When the plurality of buffer plates 520 are provided from a top portion to a bottom portion, the plurality of buffer plates 520 may be provided such that the heat transfer rate thereof gradually decreases from a top portion to a bottom portion. Optionally, as illustrated in FIG. 12, the buffer plate 520 may not be provided in the electrostatic chuck 501f.

In the exemplary embodiment of the present invention, in the electrostatic chuck 501, the top block 502 and the bottom block 503 are bonded to each other by the bonding layer 504. A first plate provided with a heater is disposed in the top block 502, and a second plate having a lower heat transfer rate than the first plate is disposed between the first plate and the bottom block 503. Accordingly, damage to the bonding layer 504 due to thermal impact by high-temperature heat generated in the heater is minimized. Therefore, even in a high-temperature process in which the substrate W is treated at a temperature higher than 150° C., the process can be performed without damage to the bonding layer 504.

When the ceramic puck 510 includes the upper plate 510a and the lower plate 510b, the upper plate 510a may function as the first plate and the lower plate 510b may function as the second plate. When the ceramic puck 510 has only one plate, the ceramic puck 510 may function as the first plate and the buffer plate 520 may function as the second plate.

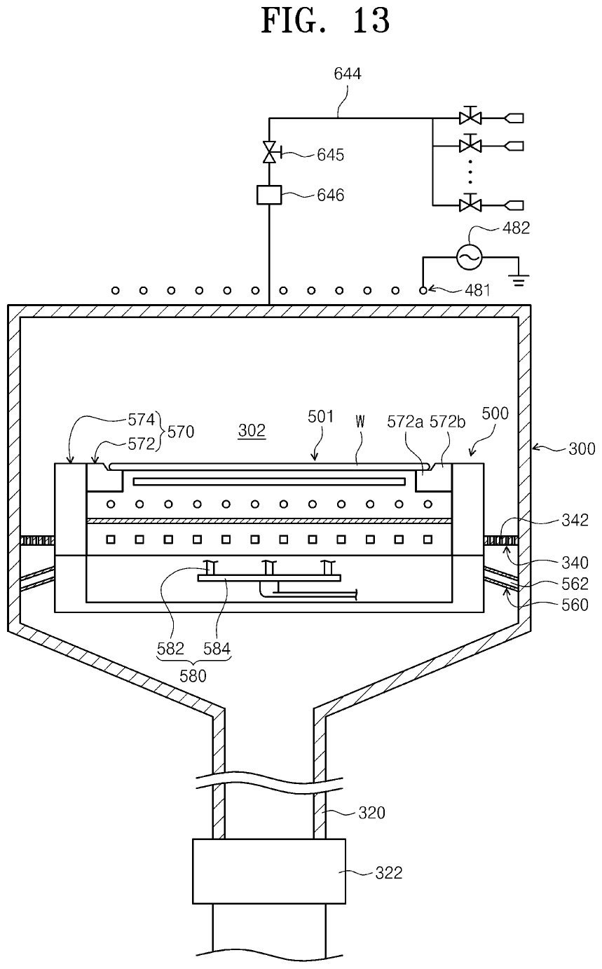

In FIG. 3, it has been illustrated that the shower head unit 400 and the support unit 500 are provided to face each other in the housing 300, and electrodes are supplied to each of the shower head unit and the support unit 500, thereby generating plasma by capacity coupling. However, in contrast, the plasma generating unit may be provided in a structure in which plasma is generated by induction coupling in the treating space by applying high frequency power from a high frequency power source 482 to an antenna 481 disposed outside the housing 300, as illustrated in FIG. 13. The antenna is disposed at a position adjacent to an upper wall of the housing, and the upper wall of the housing may be implemented with a dielectric window. Optionally, the plasma generating unit may be provided in a structure in which plasma is generated from the treatment gas in an outer space of the housing and the generated plasma is introduced into the housing.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

What is claimed is:

1. An apparatus for treating a substrate, comprising:
a housing having a treatment space inside;
a support unit configured to support the substrate in the treatment space;
a gas supply unit configured to supply a treatment gas to the treatment space; and
a plasma generating unit configured to generate plasma from the treatment gas,
wherein the support unit includes:
a top block on which the substrate is placed;
a bottom block disposed under the top block and bonded to the top block by a bonding layer, and provided with a cooling member,
wherein the top block includes:
a first plate; and
a second plate disposed under the first plate and made of a material having a lower heat transfer rate than the first plate.

2. The apparatus for treating a substrate of claim 1, wherein each of the first plate and the second plate is made of a ceramic material, and
the first plate and the second plate are integrally provided by sintering.

3. The apparatus for treating a substrate of claim 1, further comprising:
a porous layer disposed under the first plate; and
a gas supply line configured to supply gas to the porous layer.

4. The apparatus for treating a substrate of claim 3, wherein the porous layer is inserted into the second plate.

5. The apparatus for treating a substrate of claim 3, wherein the porous layer is disposed under the second plate.

6. The apparatus for treating a substrate of claim 2, further comprising a third plate disposed under the second plate and made of a material having a lower heat transfer rate than the second plate.

7. The apparatus for treating a substrate of claim 6, wherein the third plate is made of a material with a higher heat expansion rate than the second plate.

8. The apparatus for treating a substrate of claim 1, wherein the second plate is made of a material with a higher heat expansion rate than the first plate.

9. The apparatus for treating a substrate of claim 1, wherein the first plate and the second plate are made of the same material, and the type and content of impurities contained in the first plate are different from the type and content of impurities contained in the second plate.

10. The apparatus for treating a substrate of claim 1, wherein the first plate includes a heating member configured to heat the substrate.

11. An electrostatic chuck for chucking the substrate with an electrostatic force, comprising:
an top block on which the substrate is placed;
a bottom block disposed under the top block and bonded to the top block by a bonding layer and provided with a cooling member,
wherein the top block includes:
a first plate in which a chucking electrode and a heating member are installed; and
a second plate disposed under the first plate and made of a material having a lower heat transfer rate than the first plate.

12. The electrostatic chuck of claim 11, wherein each of the first plate and the second plate is made of a ceramic material, and
the first plate and the second plate are integrally provided by sintering.

13. The electrostatic chuck of claim 11, further comprising:
a porous layer disposed under the first plate; and
a gas line configured to supply gas to the porous layer.

14. The electrostatic chuck of claim 11, further comprising: a third plate disposed under the second plate and provided with a material having a lower heat transfer rate than the second plate.

15. The electrostatic chuck of claim 14, wherein the third plate is made of a material with a higher heat expansion rate than the second plate.

16. The electrostatic chuck of claim 11, wherein the second plate is made of a material having a higher heat expansion rate than the first plate.

17. An apparatus for treating a substrate, comprising:
a housing having a treatment space inside;
an electrostatic chuck configured to support the substrate by an electrostatic force in the treatment space;
a gas supply unit configured to supply a treatment gas to the treatment space; and
a plasma generating unit configured to generate plasma from the treatment gas,
wherein the electrostatic chuck includes:
a top block on which the substrate is placed;
a bottom block disposed under the top block and bonded to the top block by a bonding layer, and having a flow path through which a cooling fluid flows,
the bonding layer is provided as a thermal barrier layer, and
the top block includes:
a first plate provided with a heater and a chucking electrode;
a second plate disposed under the first plate and made of a material having lower heat transfer rate than the first plate; and
a third plate disposed under the second plate and provided with a material having a lower heat transfer rate than the second plate.

18. The apparatus for treating a substrate of claim 17, wherein the first plate and the second plate are made of the same material, and the type and content of impurities contained in the first plate are different from the type and content of impurities contained in the second plate.

19. The apparatus for treating a substrate of claim 18, wherein the material of the bonding layer includes silicon, and
the materials of the first plate and the second plate include aluminum nitride, and
the material of the third plate includes yttria or cordierite.

20. The apparatus for treating a substrate of claim 17, further comprising:
a porous layer disposed inside the second plate or between the second plate and the third plate; and
a gas line configured to supply gas to the porous layer.
